(19) United States
(12) Patent Application Publication
(10) Pub. No.: US 2026/0173870 A1
(43) Pub. Date: Jun. 18, 2026

(54) SEMICONDUCTOR DEVICE PACKAGE HAVING HIGH BREAKDOWN VOLTAGE INSULATION STRUCTURE WITH ENHANCED HEAT DISSIPATION FUNCTION

(71) Applicant: VCTECH Co., Ltd., Incheon (KR)

(72) Inventors: Sung Ho CHOI, Suwon-si (KR); Won Yong AN, Suwon-si (KR)

(73) Assignee: VCTECH Co., Ltd., Incheon (KR)

(21) Appl. No.: 19/418,907

(22) Filed: Dec. 12, 2025

(30) Foreign Application Priority Data
Dec. 16, 2024 (KR) 10-2024-0187017

(51) Int. Cl. H10W 40/20; H10W 40/73

(52) U.S. Cl. CPC H10W 40/237; H10W 40/73

(57) ABSTRACT

A semiconductor device package includes heat dispersion heat sinks each having semiconductor switching devices installed thereon; a silicone sheet stacked to contact each heat dispersion heat sink; a heat dissipation heat sink having a flat plate portion on which silicone sheets are seated; supporters supporting the periphery of the silicone sheet; molding outer wall frames assembled along the outer line of the heat dispersion heat sink; corner connectors installed on the upper surface of the flat plate portion to correspond to the corners of the heat dispersion heat sink, and connecting the ends of the molding outer wall frames; water cooling type heat pipes installed on the back surface of the heat dissipation heat sink; and cooling plates installed to be orthogonal to the axial direction of the water cooling type heat pipes with the water cooling type heat pipes passing through the plurality of cooling plates.

### BACKGROUND

### 1. Technical Field

The present disclosure relates to a semiconductor device package mounted in an electric train, and more specifically, to a semiconductor device package having a high breakdown voltage insulation structure with an enhanced heat dissipation function that has a package structure satisfying the high breakdown voltage standard of a semiconductor switching device to prevent insulation breakdown and has an enhanced heat dissipation function through a combination of natural cooling by ram air and water cooling type heat exchange, thereby significantly improving the integration density of semiconductor switching devices.

### 2. Related Art

In general, power supply devices used in the electrical and electronic fields are equipped with power semiconductor switching devices that switch at high speeds. In particular, an insulated gate bipolar transistor (IGBT) is capable of high voltage switching, and a drain/source portion is in the form of a general transistor to have PTC characteristics unlike an FET. Therefore, the insulated gate bipolar transistor has the advantage of being advantageous for parallel operation, and thus, is being used in not only railway vehicles but also electric vehicles and various home appliances equipped with high-efficiency motors.

Power semiconductor switching devices used in a wide range of industrial fields are required to have high breakdown voltage characteristics to endure high voltages on the basis of their characteristics. In addition, in an environment where power semiconductor switching devices are switched at high speed, thermal damage to parts or malfunction of power supply devices may be caused due to heat generation of the power semiconductor switching devices, and thus, the power semiconductor switching devices are usually packaged together with a heat dissipation device.

One thing that requires special attention when manufacturing semiconductor device packages is to maintain insulation between package components. In this regard, because a heat dissipation function may be degraded by an insulation structure, measures to enhance the insulation structure while maintaining high heat dissipation characteristics is necessary.

In particular, semiconductor device packages used in vehicles need to operate for long periods of time without failure even in high-speed driving environments, and need to have characteristics that prevent insulation breakdown even under strong vibrations. Therefore, the semiconductor device packages need to have a more stringent high breakdown voltage insulation structure compared to those in other industrial fields. However, in order to increase the number of semiconductor switching devices that can be integrated within a package when semiconductor devices are fabricated to have a high breakdown voltage insulation structure, a more effective heat dissipation function is required.

### PRIOR ART LITERATURES

### Patent Documents

Korean Patent Laid-open Publication No. 10-1998-0037815

### SUMMARY

The present disclosure is directed to providing a semiconductor device package mounted in an electric train, and an object of the present disclosure is to provide a semiconductor device package having a high breakdown voltage insulation structure with an enhanced heat dissipation function that has a high breakdown voltage insulation structure for preventing insulation breakdown even with vibrations of a vehicle by using a silicone sheet and a molding structure and at the same time has an enhanced heat dissipation function through a combination of natural cooling by ram air and water cooling type heat exchange, thereby being capable of significantly improving the integration density of semiconductor switching devices.

A semiconductor device package having a high breakdown voltage insulation structure with an enhanced heat dissipation function according an embodiment of the present disclosure includes: a plurality of heat dispersion heat sinks each having a plurality of semiconductor switching devices installed on the upper surface thereof, and dispersing heat from the semiconductor switching devices; a thermally conductive silicone sheet stacked to contact the lower surface of each of the plurality of heat dispersion heat sinks; a heat dissipation heat sink having a flat plate portion on which a plurality of silicone sheets are seated; supporters coupled to the upper surface of the flat plate portion at predetermined intervals along the outer line of the silicone sheet, and supporting the periphery of the silicone sheet on the upper surface of the flat plate portion; molding outer wall frames assembled along the outer line of the heat dispersion heat sink on the upper surface of the flat plate portion; corner connectors installed on the upper surface of the flat plate portion to correspond to the corners of the heat dispersion heat sink, and connecting the ends of the molding outer wall frames; a plurality of water cooling type heat pipes installed on the back surface of the heat dissipation heat sink, and having cooling water circulated therein; and a plurality of cooling plates installed at predetermined intervals so as to be orthogonal to the axial direction of the water cooling type heat pipes with the water cooling type heat pipes passing through the plurality of cooling plates.

In a semiconductor device package having a high breakdown voltage insulation structure with an enhanced heat dissipation function according to another embodiment of the present disclosure, a molding member formed of an insulating material is filled between the heat dispersion heat sink and the molding outer wall frames.

In a semiconductor device package having a high breakdown voltage insulation structure with an enhanced heat dissipation function according to another embodiment of the present disclosure, the heat dispersion heat sink has a plurality of projections that project laterally outward along the perimeter thereof, concave portions that are recessed inward between the projections, and step portions that project downward such that the silicone sheet is attached to the lower surfaces of the step portions.

In a semiconductor device package having a high breakdown voltage insulation structure with an enhanced heat dissipation function according to another embodiment of the present disclosure, the water cooling type heat pipe is installed so that its longitudinal axis has a predetermined inclination angle with respect to an axis perpendicular to the back surface of the heat dissipation heat sink.

In a semiconductor device package having a high breakdown voltage insulation structure with an enhanced heat dissipation function according to another embodiment of the present disclosure, the inclination angle is 10 to 15 degrees.

According to the semiconductor device package having a high breakdown voltage insulation structure with an enhanced heat dissipation function of the present disclosure, effects are provided in that the semiconductor device package has a high breakdown voltage insulation structure for preventing insulation breakdown even with vibrations of a vehicle by using a silicone sheet and a molding structure and at the same time has an enhanced heat dissipation function through a combination of natural cooling by ram air and water cooling type heat exchange, thereby being capable of significantly improving the integration density of semiconductor switching devices.

### BRIEF DESCRIPTION OF THE DRAWINGS

FIG. 1 is an exploded perspective view of a semiconductor device package having a high breakdown voltage insulation structure with an enhanced heat dissipation function according to the present disclosure.

FIG. 2 is a perspective view illustrating a state in which components exploded in FIG. 1 are coupled.

FIG. 3 is a side view illustrating the semiconductor device package having a high breakdown voltage insulation structure with an enhanced heat dissipation function according to the present disclosure.

### DETAILED DESCRIPTION

Specific embodiments according to the present disclosure will be described below with reference to the accompanying drawings. However, this is not intended to limit the present disclosure to any particular embodiment, and is to be understood to include all modifications, equivalents, and substitutions that fall within the idea and technical scope of the present disclosure.

Throughout the specification, parts having like configuration and operation are designated by the same reference signs. In addition, the accompanying drawings of the present disclosure are for the sake of convenience in illustration only, and shapes and relative dimensions thereof may be exaggerated or omitted.

In describing embodiments in detail, redundant descriptions or descriptions of techniques that are obvious to those skilled in the art are omitted. In addition, when it is mentioned in the following description that any component “includes” another component, it may be intended to include a component in addition to those mentioned, unless otherwise specifically stated.

In addition, terms such as “part,” “section,” “module” and the like used herein mean a unit that performs at least one function or operation, which may be implemented in hardware, software or a combination of hardware and software. Also, when it is mentioned that one part is electrically connected to another part, this includes not only direct connections but also connections with other configurations interposed therebetween.

Terms including ordinal numbers, such as first, second and the like, may be used to describe various components, but the components are not limited by such terms. These terms are used only to distinguish one component from another. For example, without departing from the scope of the present disclosure, a second component may be named a first component, and similarly, the first component may be named the second component.

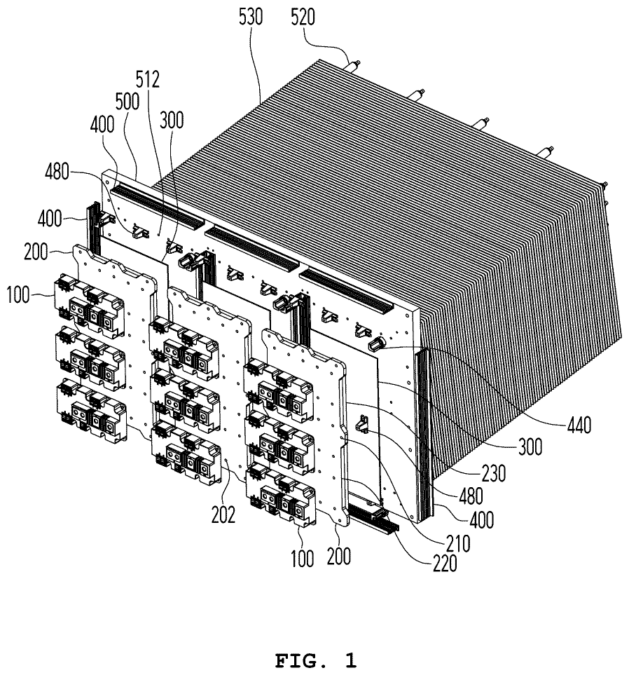

A semiconductor device package having a high breakdown voltage insulation structure with an enhanced heat dissipation function of the present disclosure provides a package structure for semiconductor switching devices mounted in an electric power-based vehicle. For example, the semiconductor switching device is an insulated gate bipolar transistor (IGBT) capable of high voltage switching. The semiconductor device package of the present disclosure provides a high breakdown voltage insulation structure that prevents insulation breakdown even with vibrations of a vehicle by using a silicone sheet having high thermal conductivity and being capable of insulation between upper and lower layers and a molding structure. In addition, the semiconductor device package of the present disclosure provides a package with an enhanced heat dissipation function by installing water cooling type heat pipes through which cooling water is circulated on the back surface of a heat dissipation heat sink to cool the semiconductor switching devices in a water cooling type and by using cooling plates installed in a direction orthogonal to the water cooling type heat pipes to allow ram air generated during vehicle travel to flow to the outer surfaces of the water cooling type heat pipes. By enhancing a heat dissipation function in this way, it is possible to provide a technical advantage that enables a plurality of semiconductor switching devices to be integrated within a single package. Hereinafter, the high breakdown voltage insulation structure and the heat dissipation structure of the semiconductor device package according to the present disclosure will be described in detail with reference to FIG. 1 to FIG. 3.

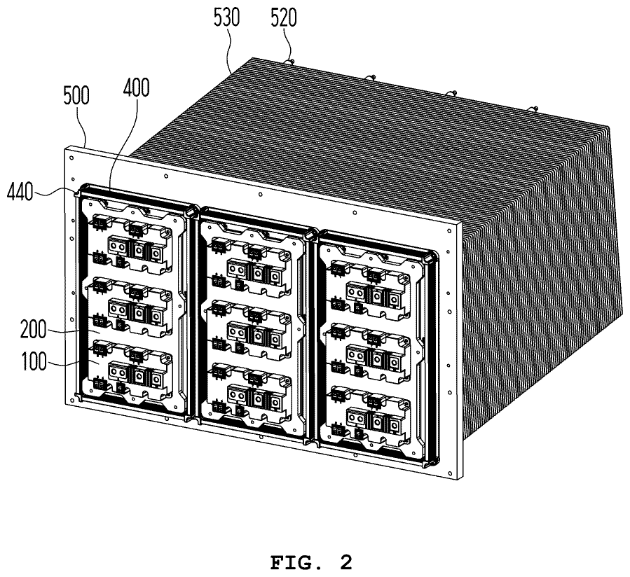

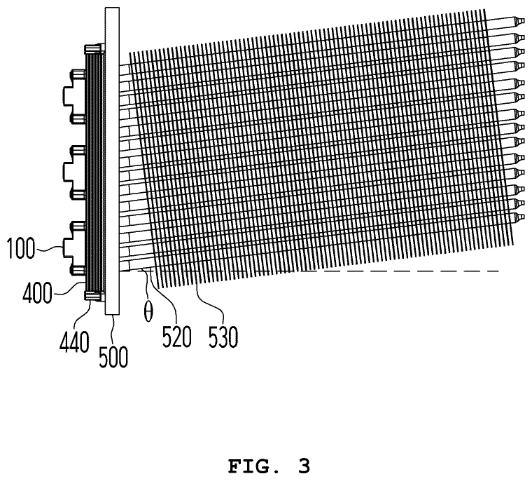

FIG. 1 is an exploded perspective view of a semiconductor device package having a high breakdown voltage insulation structure with an enhanced heat dissipation function according to the present disclosure, FIG. 2 is a perspective view illustrating a state in which components exploded in FIG. 1 are coupled, and FIG. 3 is a side view illustrating the semiconductor device package having a high breakdown voltage insulation structure with an enhanced heat dissipation function according to the present disclosure.

Referring to FIG. 1, the semiconductor device package of the present disclosure has a structure in which a heat dispersion heat sink 200 having installed thereon semiconductor switching devices 100, a silicone sheet 300 and a heat dissipation heat sink 500 for dissipating heat from the semiconductor switching devices 100 to the outside are sequentially stacked.

On the upper surface of the heat dissipation heat sink 500, a plurality of heat dispersion heat sinks 200 corresponding to a plurality of silicone sheets 300, respectively, are installed by the medium of the plurality of silicone sheets 300. A plurality of semiconductor switching devices 100 are installed on the heat dispersion heat sinks 200. In the illustrated example, it is illustrated that three semiconductor switching devices 100 are installed on each of three heat dispersion heat sinks 200 and a total of nine semiconductor switching devices 100 are accommodated in one package. However, the installation number of semiconductor switching devices 100 may be increased or decreased.

In order to independently compartment and install the plurality of respective heat dispersion heat sinks 200 on the upper surface of the heat dissipation heat sink 500 and to confine a molding liquid for high breakdown voltage insulation into respective compartmented modules, molding outer wall frames 400, corner connectors 440 for coupling and fixing the molding outer wall frames 400, and supporters 480 for supporting the heat dispersion heat sinks 200 at a uniform height are assembled.

The heat dispersion heat sink 200 has, on the upper surface thereof, a plurality of installation holes 202 for fastening and securing the semiconductor switching devices 100. The heat dispersion heat sink 200 serves as a heat sink for primarily dispersing heat generated from the semiconductor switching devices 100, and its upper plate has a plurality of projections 210 that project laterally outward along the perimeter thereof, and concave portions 220 that are recessed inward between the projections 210. As the projections 210 and the concave portions 220 form large uneven contours along the perimeter of the heat dispersion heat sink 200, the molding liquid to be impregnated into the package may be induced to flow well into the space below the upper plate.

Step portions 230 are formed on the lower surface of the heat dispersion heat sink 200 to project downward such that the silicone sheet 300 is attached to the lower surfaces of the step portions 230.

The silicone sheet 300 is formed of a thermally conductive silicone material, and is used to insulate the heat dispersion heat sink 200 and the heat dissipation heat sink 500 from each other while transferring heat from the heat dispersion heat sink 200 to the heat dissipation heat sink 500. Preferably, the silicone sheet 300 has a thermal conductivity of 1 W/m·K, and thermal conductivity may be adjusted by adjusting the thickness of the silicone sheet 300.

Referring to FIG. 1, the supporters 480 that are installed at predetermined intervals on the upper surface of the heat dissipation heat sink 500 support the periphery of the silicone sheet 300 so that the silicone sheet 300 may be assembled in the correct position. The upper surfaces of the supporters 480 are in contact with the lower surface of the upper plate of the heat dispersion heat sink 200, and allow the heat dispersion heat sink 200 to be supported at a uniform height.

The heat dissipation heat sink 500 is formed with a plurality of installation holes 512 on a flat plate portion formed at the top thereof so that package components may be installed using fastening means such as bolts. Under the flat plate portion, there are installed a plurality of water cooling type heat pipes 520 through which cooling water is circulated, and a plurality of cooling plates 530 that are disposed at predetermined intervals to be orthogonal to the axial direction of the water cooling type heat pipes 520 with the water cooling type heat pipes 520 passing through the plurality of cooling plates 530 are installed. The cooling process using the water cooling type heat pipes 520 and the cooling plates 530 will be described later with reference to FIG. 3.

Referring to FIG. 1, the molding outer wall frames 400 are assembled along the outer line of each heat dispersion heat sink 200 on the upper surface of the heat dissipation heat sink 500. Both ends of the molding outer wall frame 400 are fastened and secured by the corner connectors 440.

The molding outer wall frames 400 each are manufactured in the shape of a bar by extruding a lightweight metal material (e.g., aluminum), and are disposed to form a frame spaced apart from the outermost line of the heat dispersion heat sink 200.

The molding outer wall frame 400 has a wall portion that stands at a predetermined height to cover the heat dispersion heat sink 200 on the basis of the cross-sectional shape of an elongate member. A plurality of molding coupling pins that project inward toward the heat dispersion heat sink 200 may be provided on the wall portion of the molding outer wall frame 400. Therefore, in the subsequent process of injecting and curing a molding liquid between the molding outer wall frames 400 and the heat dispersion heat sink 200, the cured molding material is firmly coupled to the molding outer wall frames 400, and a secondary insulation structure by the molding material is not easily destroyed.

A plurality of swelling prevention grooves may be provided outside the wall portion of the molding outer wall frame 400. Therefore, when vibration is applied to the package and stress is generated in the outward direction of the frame, the swelling prevention grooves may absorb the stress, thereby preventing the frame from swelling outward.

The corner connector 440 may have two frame insertion slots that are disposed toward the ends of the molding outer wall frames 400. As the ends of the molding outer wall frames 400 are coupled to the two frame insertion slots, the molding liquid may be prevented from leaking or flowing outward, and the molding outer wall frames 400 may be firmly fixed to the package.

Referring to FIG. 3, in the semiconductor device package of the present disclosure, the plurality of water cooling type heat pipes 520 are installed on the back surface of the heat dissipation heat sink 500. The water cooling type heat pipes 520 are installed to extend through the interior of the heat dissipation heat sink 500, and transport cooling water close to the semiconductor switching devices 100.

Preferably, as illustrated in FIG. 3, the water cooling type heat pipe 520 is installed so that its longitudinal axis has a predetermined inclination angle θ with respect to an axis perpendicular to the back surface of the heat dissipation heat sink 500. For example, the inclination angle is 10 to 15 degrees.

Referring to FIG. 3, the plurality of cooling plates 530 are installed at predetermined intervals so as to be orthogonal to the axial direction of the water cooling type heat pipes 520. Since the water cooling type heat pipes 520 are installed to have the inclination angle as illustrated in FIG. 3, the cooling plates 530 are installed in a form that is closer to the heat dissipation heat sink 500 in an upper region but is farther from the heat dissipation heat sink 500 in a lower region when viewed on FIG. 3. Accordingly, a space is formed in the lower region of the heat dissipation heat sink 500 where ram air may flow in and stay.

That is to say, when viewing the heat dissipation heat sink 500 from the side, the cooling plates 530 are installed to be inclined so that a sufficient space for ram air to flow in is formed in the lower region of the heat dissipation heat sink 500. Depending on a direction in which a vehicle travels, ram air flows into the inclined gaps of the cooling plates 530, and comes into contact with the outer surfaces of the water cooling type heat pipes 520 to rapidly cool the water cooling type heat pipes 520. In particular, in the lower space formed by the predetermined inclination angle, the introduced wind may stay to increase cooling performance for the heat dissipation heat sink 500.

If the inclination angle of the water cooling type heat pipes 520 with respect to the heat dissipation heat sink 500 is less than 10 degrees, the effect of allowing ram air to flow in and stay is reduced, and if the inclination angle is greater than 15 degrees, a too much space may be formed under the cooling plates 530 and installation of the water cooling type heat pipes 520 may become difficult. Accordingly, it is preferable that the inclination angle be 10 to 15 degrees.

The present disclosure described above may be modified diversely without departing from the basic idea of the present disclosure. In other words, all of the above embodiments are to be construed as examples and not limiting. Accordingly, the protection scope of the present disclosure should be defined by the appended claims, not by the above embodiments, and any substitution of a component defined in the appended claims with an equivalent should be considered as falling within the protection scope of the present disclosure.

What is claimed is:

1. A semiconductor device package having a high breakdown voltage insulation structure with an enhanced heat dissipation function, comprising:
a plurality of heat dispersion heat sinks each having a plurality of semiconductor switching devices installed on the upper surface thereof, and dispersing heat from the semiconductor switching devices;
a thermally conductive silicone sheet stacked to contact the lower surface of each of the plurality of heat dispersion heat sinks;
a heat dissipation heat sink having a flat plate portion on which a plurality of silicone sheets are seated;
supporters coupled to the upper surface of the flat plate portion at predetermined intervals along the outer line of the silicone sheet, and supporting the periphery of the silicone sheet on the upper surface of the flat plate portion;
molding outer wall frames assembled along the outer line of the heat dispersion heat sink on the upper surface of the flat plate portion;
corner connectors installed on the upper surface of the flat plate portion to correspond to the corners of the heat dispersion heat sink, and connecting the ends of the molding outer wall frames;
a plurality of water cooling type heat pipes installed on the back surface of the heat dissipation heat sink, and having cooling water circulated therein; and
a plurality of cooling plates installed at predetermined intervals so as to be orthogonal to the axial direction of the water cooling type heat pipes with the water cooling type heat pipes passing through the plurality of cooling plates.

2. The semiconductor device package having a high breakdown voltage insulation structure with an enhanced heat dissipation function according to claim 1, wherein a molding member formed of an insulating material is filled between the heat dispersion heat sink and the molding outer wall frames.

3. The semiconductor device package having a high breakdown voltage insulation structure with an enhanced heat dissipation function according to claim 1, wherein the heat dispersion heat sink has a plurality of projections that project laterally outward along the perimeter thereof, concave portions that are recessed inward between the projections, and step portions that project downward such that the silicone sheet is attached to the lower surfaces of the step portions.

4. The semiconductor device package having a high breakdown voltage insulation structure with an enhanced heat dissipation function according to claim 1, wherein the water cooling type heat pipe is installed so that its longitudinal axis has a predetermined inclination angle with respect to an axis perpendicular to the back surface of the heat dissipation heat sink.

5. The semiconductor device package having a high breakdown voltage insulation structure with an enhanced heat dissipation function according to claim 4, wherein the inclination angle is 10 to 15 degrees.

6. The semiconductor device package having a high breakdown voltage insulation structure with an enhanced heat dissipation function according to claim 2, wherein the heat dispersion heat sink has a plurality of projections that project laterally outward along the perimeter thereof, concave portions that are recessed inward between the projections, and step portions that project downward such that the silicone sheet is attached to the lower surfaces of the step portions.
